(19) United States
(12) Patent Application Publication
(10) Pub. No.: US 2012/0211353 A1
(43) Pub. Date: Aug. 23, 2012

(54) METHOD OF COATING METAL SHELL WITH PURE WHITE FILM

(75) Inventors: CHUNG-PEI WANG, Tu-Cheng (TW); MING-YANG LIAO, Tu-Cheng (TW)

(73) Assignee: HON HAI PRECISION INDUSTRY CO., LTD., Tu-Cheng (TW)

(21) Appl. No.: 13/097,096

(22) Filed: Apr. 29, 2011

(30) Foreign Application Priority Data
Feb. 22, 2011 (TW) 100105879

(51) Int. Cl. C23C 14/35; C23C 14/06

(52) U.S. Cl. 204/192.15

(57) ABSTRACT

A method of coating a pure white film includes a first step of providing a metal shell, a second step of forming a bonding layer on a surface of the metal shell by a first magnetron sputtering process, and a third step of forming a pure white layer on a surface of the bonding layer by a second magnetron sputtering process. The bonding layer includes chromium nitride. In the second process, aluminum and chromium corporately serves as targets. Oxygen serves as a reactive gas. A ratio of a bombarding power of the aluminum to that of the chromium is about 12:1. A bias voltage ranges from 180 volts to 220 volts. The second magnetron sputtering process lasts for about 58 to 62 minutes and goes on under a temperature ranged from 180° C. to 220° C. And the pure white layer includes aluminum oxide and chromium oxide.

### BACKGROUND

1. Technical Field

The present disclosure relates to coating technology and, particularly, to a method of coating metal shell with pure white film.

2. Description of Related Art

Electronic devices with a pure white shell are usually popular. These pure white shells are generally made of plastic. However, metal shells, which are sturdy, with a pure white color are rarely seen.

Therefore, it is desirable to provide a method of coating metal shell with pure white film.

### BRIEF DESCRIPTION OF THE DRAWINGS

Many aspects of the present disclosure should be better understood with reference to the following drawings.

FIG. 1 is a flow chart showing a method of coating metal shell with pure white film, in accordance with an exemplary embodiment.

FIG. 2 is a partial, cross-sectional view of a metal shell having a bonding layer and a pure white layer that are made according to the method shown in FIG. 1.

### DETAILED DESCRIPTION

Embodiments of the present disclosure will now be described in detail with reference to the drawings.

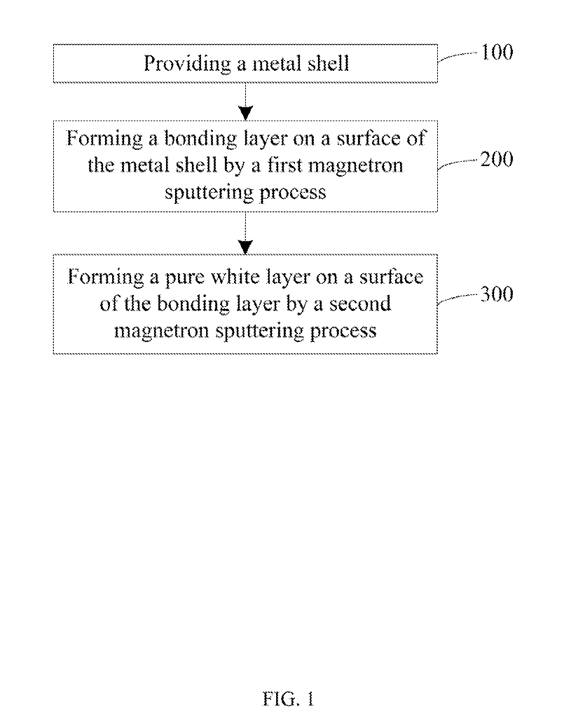

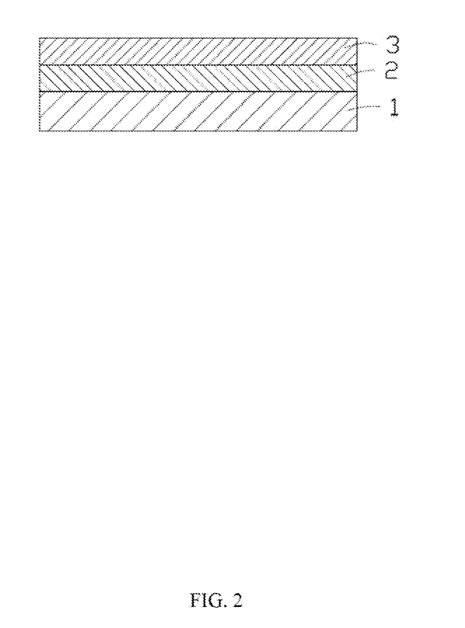

Referring to FIGS. 1 and 2, a method of coating a pure white film 3 on a metal shell 1, in accordance with an exemplary embodiment, includes the following steps.

In step 100, a metal shell 1 is provided. The metal shell 1 can be a shell of an electronic device and the material thereof can be Aluminum, stainless steel, etc.

In step 200, a bonding layer 2 is formed on a surface of the metal shell 1 by a first magnetron sputtering process. The first process is performed in a magnetron sputtering device (not shown). The magnetron sputtering device defines a chamber for carrying out the first process. Chromium serves as a target. A first magnetic field and a first electrical field are applied between the target (a cathode) and the metal shell 1 (an anode). The first magnetic field is orthogonal to the first electrical field. Then, a mixture of nitrogen and argon gases is continually introduced into the chamber during coating the bonding layer 2. The ratio of the nitrogen and the argon is 2.3 to 1. For example, the nitrogen is introduced at a flow rate of about 58 standard cubic centimeters per minute (sccm), while the argon is introduced at a flow rate of about 25 sccm. The nitrogen serves as a reactive gas that reacts with atoms of the target. The argon serves as a working gas that actives the first process. In the first electrical field, the argon is ionized to argon ions (i.e., with positive charge) and electrons. Argon ions are accelerated by the first electrical field to bombard the chromium. A number of chromium atoms then emit/release from the chromium. The chromium atoms react with the nitrogen to form chromium nitride. The chromium nitride is then deposited on the surface of the metal shell 1, forming the bonding layer 2. The bonding layer 2 enhances the adhesion between the pure white layer 3 and the metal shell 1.

In step 300, a pure white layer 3 is formed on a surface of the bonding layer 2 by a second magnetron sputtering process. The second process can also be performed in the magnetron sputtering device. In the second process, aluminum and chromium cooperatively serve as targets. A second magnetic field and a second electrical field are applied between the targets (a cathode) and the metal shell 1 (an anode). The second magnetic field is orthogonal to the second electrical field. Then, a mixture gas of oxygen and argon is continually introduced into the chamber during coating the pure white layer 3. The ratio of the oxygen and the argon is 3 to 2. For example, the oxygen is introduced at a flow rate of about 300 sccm, while the argon is introduced at a flow rate of about 200 sccm. The oxygen serves as a reactive gas. The argon serves as a working gas. The process is done at a temperature in a range of 180° C. to 220° C. In the process, the metal shell 1 is driven to rotate around a central axis thereof at 5 revolutions per minute (rpm) and, simultaneously, to rotate around a central axis of the coating chamber at −2.7 to −3.3 rpm. A ratio of a bombarding power of the aluminum to that of the chromium is about 12:1. The bias voltage is in a range of 180 to 220 volts (V). For example, a bombarding power of the aluminum is about 30 kilowatts (kW), and the bombarding power of the chromium is about 2.5 kW. In the second electrical field, the argon is ionized to argon ions and electrons. Argon ions bombard the targets. A number of aluminum and chromium atoms then emit/release from the targets and react with the oxygen to form a mixture of aluminum oxide and chromium oxide. The mixture of aluminum oxide and chromium oxide is then deposited on the surface of the bonding layer 2. When the second process has gone on for about 58 to 62 minutes, the pure white layer 3 is formed on the surface of the bonding layer 2.

Accordingly, using the chromaticity coordinate (L*, a*, b*), the pure white layer 3 of this embodiment has a value of L* in a range from about 86.15 to about 86.25, a value of a* in a range from about 0.425 to about 0.435, and a value of b* in a range from about 0.715 to about 0.725 according to the CIELAB system.

It will be understood that the above particular embodiments is shown and described by way of illustration only. The principles and the features of the present disclosure may be employed in various and numerous embodiment thereof without departing from the scope of the disclosure as claimed. The above-described embodiments illustrate the scope of the disclosure but do not restrict the scope of the disclosure.

What is claimed is:

1. A method of coating a pure white film, comprising:
a first step of providing a metal shell;
a second step of forming a bonding layer on a surface of the metal shell by a first magnetron sputtering process, the bonding layer comprising chromium nitride; and
a third step of forming a pure white layer on a surface of the bonding layer by a second magnetron sputtering process, in the second magnetron sputtering process, aluminum and chromium corporately serving as targets, oxygen serving as a reactive gas, a ratio of a bombarding power of the aluminum to that of the chromium being about 12:1, a bias voltage being at a range of 180 volts to 220 volts, the second process lasting for about 58 to 62 minutes and being done at a temperature ranged of 180° C. to 220° C., and the pure white layer comprising aluminum oxide and chromium oxide.

2. The method of claim 1, wherein in the second step, chromium serves as a target, nitrogen serves as a reactive gas, argon serves as working gas, a ratio of the nitrogen and the argon is 2.3 to 1.

3. The method of claim 2, wherein the nitrogen is introduced at a flow rate of about 58 sccm and the argon is introduced at a flow rate of about 25 sccm.

4. The method of claim 1, wherein a bombarding power of the aluminum is about 30 kW and the bombarding power of the chromium is about 2.5 kW.

5. The method of claim 1, wherein in the third step, the metal shell is driven to rotate around a central axis thereof at 5 rpm and to rotate around an axis outside of the metal shell at −2.7 to −3.3 rpm.
